(19) United States
(12) Patent Application Publication
(10) Pub. No.: US 2026/0221978 A1
(43) Pub. Date: Jul. 30, 2026

(54) SYNCHRONIZED FEED FORWARD FREQUENCY DECODER AND SCALABLE VOLTAGE CONTROLLED OSCILLATOR FOR FRACTIONAL-N PHASE LOCKED LOOP

(71) Applicant: Marvell Asia Pte Ltd, Singapore (SG)

(72) Inventors: Junhui Gu, San Jose, CA (US); Dongliang Liang, San Jose, CA (US); Xing Liu, Markham (CA); Jianmin Guo, Fremont, CA (US); Xin Ma, San Jose, CA (US); Hui Wang, Pleasanton, CA (US)

(73) Assignee: Marvell Asia Pte Ltd, Singapore (SG)

(21) Appl. No.: 19/455,168

(22) Filed: Jan. 21, 2026

Related U.S. Application Data
(60) Provisional application No. 63/749,049, filed on Jan. 24, 2025.
(60) Provisional application No. 63/752,519, filed on Jan. 31, 2025.
(60) Provisional application No. 63/761,144, filed on Feb. 20, 2025.

(51) Int. Cl. H03L 7/197; H03L 7/099

(52) U.S. Cl. CPC H03L 7/1974; H03L 7/0995

(57) ABSTRACT

A fractional-N phase locked loop (PLL) is described and includes a synchronized feed forward frequency decoder configured to generate a VCO frequency code from a feedback divider ratio and an update rate input thereto; and a scalable voltage-controlled oscillator (VCO) comprising an array of ring cells, wherein each of the ring cells comprises a multi-stage ring VCO comprising a plurality of inverters, wherein a transconductance of each of the ring cells is controlled by bias voltage signals applied to a selected one of the ring cells.

### PRIORITY APPLICATION

This patent application claims priority to and/or the benefit of U.S. Provisional Application No. 63/749,049, entitled “A 16 GHz Fractional-N PLL Achieving On-the-Fly 4× Frequency Ramping with <1.5% Frequency Settling Overshoot for Supporting AVFS in AI/Server Processors,” filed on Jan. 24, 2025, U.S. Provisional Application No. 63/752,519, entitled “Low Power and Low Spur Fractional-N PLL,” filed on Jan. 31, 2025, and U.S. Provisional Application No. 63/761,144, entitled “Multi-Ring VCO of Linear Scaling Kvco for the On-the-Fly Frequency Ramping PLL,” filed on Feb. 20, 2025, each of which is hereby incorporated by reference in its entirety.

### BACKGROUND

A phase-locked loop (PLL) is a control system that generates an output signal the phase of which is fixed relative to the phase of an input, or reference, signal. A PLL typically includes a voltage-controlled oscillator (VCO) and a phase detector (or phase comparator) such that the output frequency of the PLL is continuously adjusted according to the frequency of its input signal. PLLs are widely used in a variety of applications, including but not limited to clock recovery, demodulation in communications systems, and frequency synthesis. PLLs assist in maintaining a constant phase angle relative to a reference signal, making them invaluable in high-frequency electronics.

A fractional-N PLL employs a frequency synthesis technique that enables the output frequency step to be fraction of the reference frequency, thereby providing finer frequency resolution than an integer-N PLL. This is achieved by dynamically changing the feedback division ratio to an average value, such as N+α, where N is an integer and α is the desired fractional part.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1A illustrates a block diagram of processor module including an AI server processor, according to some embodiments of the disclosure.

FIG. 1B illustrates a block diagram of die-to-die clocking and SerDes circuitry of the processor module of FIG. 1A, according to some embodiments of the disclosure.

FIG. 2 illustrates a block diagram of an exemplary PLL, according to some embodiments of the disclosure.

FIG. 3 illustrates a schematic block diagram of a fractional-N PLL according to embodiments of the disclosure.

FIG. 4A illustrates a timing diagram of various signals associated with a synchronized feed forward frequency decoder (SFFFD) of the fractional-N PLL of FIG. 3, according to some embodiments of the disclosure.

FIG. 4B illustrates a results of MATLAB modeling of frequency ramping behavior of the SFFFD of the fractional-N PLL of FIG. 3, according to some embodiments of the disclosure.

FIG. 5 illustrates a more detailed schematic block diagram of a multi-rings VCO of a linear scaling KFCO decoder of the fractional-N PLL of FIG. 3, according to some embodiments of the disclosure.

FIGS. 6A-6D illustrate various aspects of the linear scaling KFCO decoder of FIG. the fractional-N PLL of FIG. 3, according to some embodiments of the disclosure.

FIG. 7A illustrates a more detailed schematic block diagram of a fractional feedback divider (FFD) of the fractional-N PLL of FIG. 3, according to some embodiments of the disclosure.

FIG. 7B illustrates a timing diagram of various signals associated with the FFD of FIG. 7A, according to some embodiments of the disclosure.

### DETAILED DESCRIPTION

### Overview

The performance of an AI server processor depends primarily on power consumption, inter-cores or I/O data throughput, and transport latency. Embodiments described herein include a fractional-N PLL for use in a clock system of an AI processor aimed at supporting adaptive voltage and frequency scaling (AVFS) and low data transport latency. AI server processors with scalable cores and die-to-die input/output (I/O) require PLLs to be able to achieve large-scale and rapid on-the-fly frequency ramping with minimal period jitter. Such a PLL adjusts the system clock frequency in real-time based on processing tasks, optimizing power efficiency without needing a reset. The PLL may also need sufficiently low long-term jitter to align the inter-channel timing of die-to-die I/O or the intercore timing of the processor, synchronizing the data without a FIFO, thus achieving low latency.

The fractional-N PLL described herein achieves 4× on-the-fly frequency ramping with <1.5% frequency settling overshoot by utilizing various techniques, including a synchronized feed-forward frequency decoder (SFFFD), a multi-rings VCO with linear scaling VCO gain (KVCO), and a low spur and low power consumption fractional feedback divider (FFD). When fabricated in 3 nm FinFET technology, the proposed PLL may occupy a die area of approximately 0.01275 mm² and achieves 1.12 ps_{RMS} long term jitter and 0.826 ps spur jitter when the VCO oscillates at 15 GHz.

### Exemplary AI Server Processor

An AI/server processor is a high-performance integrated circuit designed to execute compute-intensive workloads, such as AI inference, training, and large-scale server operations. Such AI/server processors typically include several common components, including a scalable core complex, a die-to-die interconnect (I/O subsystem), PLLs, memory hierarchy, and power and thermal management.

A scalable core complex may include a plurality of processing cores arranged in a scalable architecture to support varying performance and power requirements. Each core may include vector or matrix acceleration units optimized for AI workloads, along with general-purpose execution pipelines for server tasks. The cores may be interconnected through a high-bandwidth on-die fabric, enabling low-latency communication and dynamic workload distribution.

A die-to-die interconnect, or I/O subsystem, may include high-speed die-to-die interfaces for connecting multiple processor dies within a package or across chiplets, which interfaces may utilize advanced signaling techniques to achieve low latency and high throughput for memory access and inter-processor communication. The I/O subsystem often supports coherent protocols to maintain data consistency across dies.

PLL circuits maybe employed to generate and synchronize clock signals for the processor cores and I/O interfaces. Multiple PLLs may be distributed across the die to provide localized clock domains, ensuring timing integrity for high-speed links and scalable core clusters. PLLs may also enable dynamic frequency scaling to optimize performance and power efficiency.

Memory hierarchy may include integrated cache structures (e.g., L1, L2, and shared L3) for reducing memory access latency. External memory controllers may be provided for supporting DDR, HBM, or other high-bandwidth memory technologies for large-scale data processing.

Power and thermal management may include on-die power delivery networks and voltage regulators for fine-grained control of core and I/O power states. Thermal sensors and dynamic throttling mechanisms may be provided to maintain operational reliability under heavy workloads.

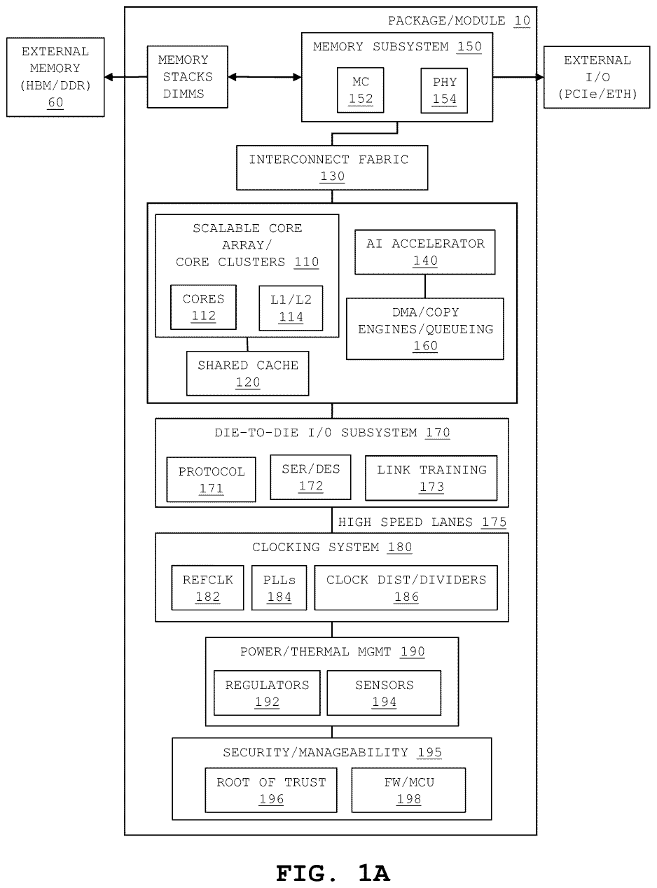

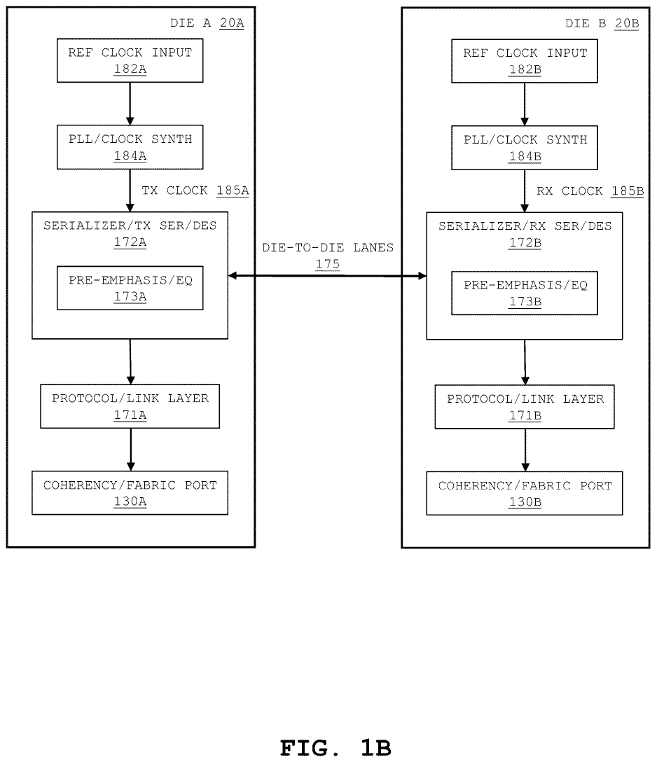

FIG. 1A illustrates a processor module 10 including an AI/server processor 100 configured for scalable compute throughput and multi-die expansion. Processor 100 includes scalable core array 110 coupled to interconnect fabric 130. Scalable core array 110 includes a plurality of processor cores 112 arranged as one or more core clusters, core tiles, or core complexes, with private or semi-private cache resources such as L1/L2 cache 114. Interconnect fabric 130 provides communication among scalable core array 110, shared cache 120, AI accelerator 140, memory subsystem 150, and die-to-die I/O subsystem 170. Shared cache 120 provides a shared last-level cache (LLC), system-level cache (SLC), or another shared caching structure supporting reduced off-die bandwidth demand and reduced average memory access latency for workloads including AI inference, AI training, and server processing.

AI accelerator 140 includes one or more fixed-function or programmable engines that execute matrix, vector, or tensor operations, with data paths supporting parallel multiply-accumulate (MAC) operations and optional sparsity, quantization, or mixed-precision processing. DMA/copy engines 160 support movement of data among shared cache 120, memory subsystem 150, AI accelerator 140, and peripheral interfaces, with queueing structures and command processors supporting asynchronous transfers, scatter-gather operations, and memory-to-memory copy operations.

Memory subsystem 150 includes one or more memory controllers 152 and one or more memory physical interfaces (PHYs) 154 that couple processor 100 to external memory 60. External memory 60 includes high-bandwidth memory (HBM), double data rate memory (DDR), or another memory technology. Memory controller 152 supports scheduling, refresh, ordering rules, and quality-of-service (QoS) arbitration, while memory PHY 154 supports high-speed signaling, training, and calibration for memory channels.

Die-to-die I/O subsystem 170 provides high-speed communication between processor 100 and at least one additional die or chiplet within module 10. Die-to-die I/O subsystem 170 includes protocol layer 171, serializer/deserializer circuitry (SerDes) 172, and link training/equalization circuitry 173. Protocol layer 171 supports packetization, ordering, flow control, and optional coherency semantics for transactions that traverse die-to-die lanes 175. Link training/equalization circuitry 173 supports lane initialization, deskew, equalization setting selection, margining, and retry behavior. Die-to-die lanes 175 support high-throughput point-to-point signaling implemented as parallel single-ended lanes, differential lanes, or a combination thereof, with optional forward error correction (FEC) and cyclic redundancy check (CRC) protection. In some embodiments, die-to-die I/O subsystem 170 supports coherent communication that maintains cache coherence across shared cache 120 instances distributed across multiple dies, with protocol layer 171 exchanging coherence messages and associated data payloads over die-to-die lanes 175.

Clocking system 180 supports timing generation and distribution for scalable core array 110, interconnect fabric 130, memory subsystem 150, and die-to-die I/O subsystem 170. Clocking system 180 includes reference clock source 182, one or more phase-locked loops (PLLs) 184, and clock distribution/divider circuitry 186. Reference clock source 182 provides a reference frequency derived from an oscillator, board clock, or package-distributed clock. PLL 184 generates one or more synthesized clocks having frequencies and phases suitable for core clock domains, fabric clock domains, memory clock domains, and I/O clock domains. PLL 184 provides frequency multiplication and optional fractional synthesis, jitter filtering, and phase alignment to support timing closure for high-speed interfaces. Clock distribution/divider circuitry 186 distributes synthesized clocks to clock domains and may include dividers, multiplexers, glitchless clock switching logic, clock gating cells, and clock-domain-crossing (CDC) support circuitry. In some embodiments, clocking system 180 includes separate PLL instances 184 assigned to distinct domains, including a core PLL instance supporting scalable core array 110 and an I/O PLL instance supporting die-to-die I/O subsystem 170, with independent voltage and frequency scaling per domain.

Power and thermal management subsystem 190 supports power delivery and reliability for processor 100. Subsystem 190 includes voltage regulation circuitry 192 and sensor circuitry 194. Voltage regulation circuitry 192 includes integrated voltage regulators, low-dropout regulators, switched-capacitor regulators, or digitally controlled external regulator interfaces. Sensor circuitry 194 includes temperature sensors, voltage monitors, current monitors, and performance counters used to enforce power limits and thermal limits. In some embodiments, subsystem 190 controls dynamic voltage and frequency scaling (DVFS) via control of PLL 184 and domain voltage rails, with policies that maintain performance targets while satisfying thermal and power constraints.

Security/manageability subsystem 195 supports platform security and operational management. Subsystem 195 includes root-of-trust circuitry 196 and management controller or firmware processor 198. Root-of-trust circuitry 196 supports secure boot, key storage, attestation, and cryptographic primitives. Management controller 198 supports telemetry, debug access controls, and lifecycle management functions including configuration of die-to-die I/O subsystem 170, configuration of clocking system 180, and configuration of power/thermal management subsystem 190.

FIG. 1B illustrates a die-to-die lane clocking arrangement implemented by die 20A coupled to die 20B through die-to-die lanes 175. Die 20A includes reference clock input 182A coupled to PLL 184A. PLL 184A generates transmit (TX) clock 185A that drives serializer/TX SerDes 172A. Serializer/TX SerDes 172A transmits serialized data over die-to-die lanes 175 with link conditioning via equalization circuitry 173A. Die 20B includes reference clock input 182B coupled to PLL 184B. In an embodiment, PLL 184B generates one or more receive (RX) clocks 185B that support sampling and recovery for deserializer/RX SerDes 172B. In another embodiment, deserializer/RX SerDes 172B includes clock-data recovery (CDR) within circuitry 173B that recovers sampling phase from transitions embedded in lane signaling, with PLL 184B providing a low-jitter local reference used for CDR loop stability or retiming. Protocol/link layer 171A and protocol/link layer 171B perform link initialization, lane alignment, deskew, and integrity checks, then present transactions to coherency/fabric ports 130A and 130B. Arrangement supports scalable multi-die construction by replicating die-to-die instances and scaling lane counts, with PLL instances supporting clock-domain isolation and jitter management for increasing link speeds.

### PLL Fundamentals

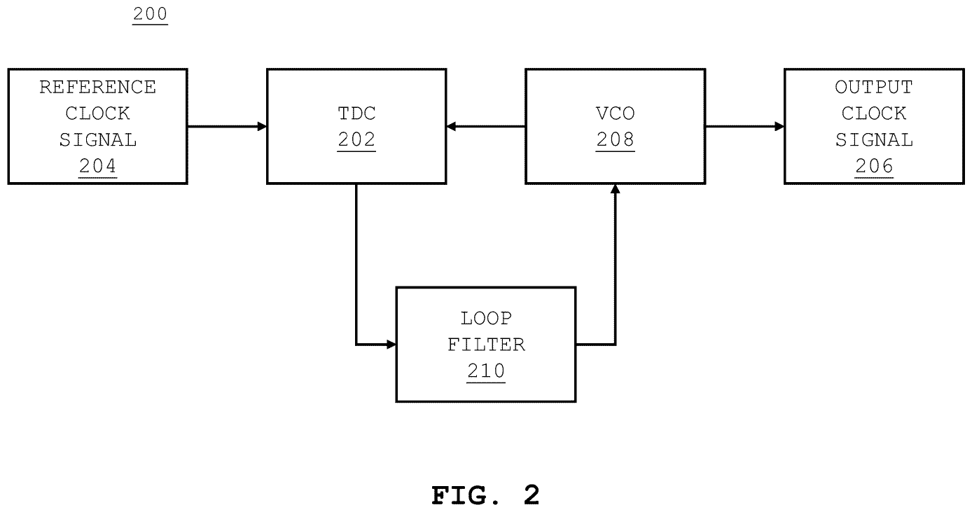

FIG. 2 illustrates a PLL 200, which, as previously noted, is a control system that uses a feedback loop to synchronize, or lock, the phase of an output signal with that of a reference signal. When the signal phases are locked, the output frequency is typically a multiple of the reference frequency. PLL 200 may be included as a component of a variety of electronic devices, such as computing system 100 (FIG. 1) and/or components thereof.

As shown in FIG. 2, PLL 200 includes a phase detector 202 which compares the phase of an input reference signal, or reference clock signal, 204 with an output signal 206 from a VCO 208. A loop filter 210 is provided for smoothing the output of phase detector 202, removing unwanted high-frequency components and providing a DC voltage proportional to the phase difference. The frequency of VCO 208 is controlled by the DC voltage from loop filter 210. As the frequency of VCO 208 changes, the phase of output signal changes 206, eventually aligning with that of reference signal 204. In some applications, a frequency divider (not shown in FIG. 2) 212 may be provided to reduce the frequency of output signal 206 before it is compared to reference signal 204 by the phase detector 202.

In operation, phase detector 202 compares the phase of input reference signal 204 and output signal 206. Loop filter 210 smooths the output of phase detector 202, creating a DC voltage provided to VCO 208. The frequency of VCO is adjusted based on the DC voltage from loop filter 210. This process is repeated until the phase difference between input reference signal 204 and output signal 206 is minimized or essentially eliminated, at which point the loop is deemed locked.

### Exemplary Fractional-N PLL

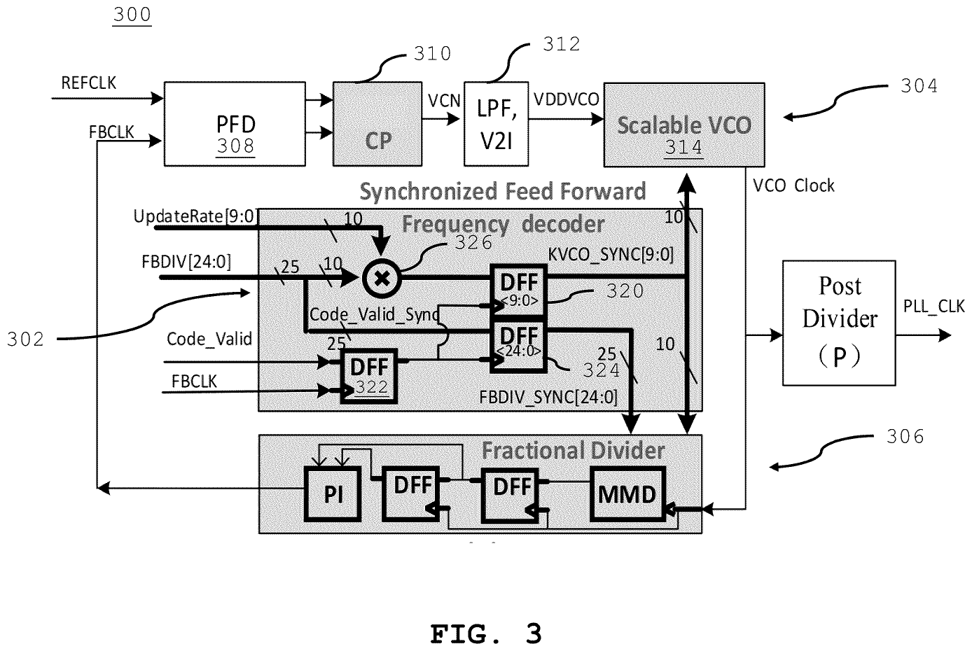

FIG. 3 illustrates a schematic block diagram of a fractional-N PLL 300 according to features of embodiments described herein. As shown in FIG. 3, fractional-N PLL 300 includes an SFFFD 302, a multi-rings VCO with linear scaling KVCO 304, and a fractional feedback divider (FFD) 306. As will be described in greater detail below, multi-rings VCO with linear scaling KVCO 304 includes a phase frequency detector (PFD) 308, a charge pump (CP) 310, a low pass filter (LPF)/voltage-to-current converter (V2I) element 312, and a scalable VCO 314.

A charge pump is a core component in many modern PLLs, particularly digital or mixed-signal PLLs. A charge pump converts the digital error signals from the PFD (e.g., PFD 308) into a proportional current or voltage that charges or discharges a loop filter capacitor, resulting in a control voltage (VCN).

Equation 1 expresses the PLL output frequency, where FBDIV[24:16] is the integer part and FBDIV[15:0] is the fractional part of a feedback divider ratio. FREF is the frequency of the reference clock (REFCLK), and P is a post divider code.

$${F}_{VCO} = {F}_{R E F} * \frac{FBDIV [ 24 : 0 ]}{{2}^{15}} * \frac{1}{P} \qquad ( 1 )$$

Each of SFFFD 302, multi rings VCO 304, and FFD 306 will be described in greater detail hereinbelow.

### Exemplary Behavior of SFFFD for Fractional-N PLL

In a conventional PLL without an SFFFD, such as SFFFD 302, once the feedback divider ratio is updated to change the frequency of the PLL, phase error will start to accumulate between feedback clock (FBCLK) and REFCLK at the input of the PFD thereof due to sudden change in feedback divider ratio. This big initial phase error is problematic for period jitter due to the PLL having a frequency overshoot during its settling time. From the perspective of the PLL loop, the VCO output frequency (FVCO) can be expressed as Equation (2). Since the oscillation frequency of the VCO follows Equation (3), VDDVCO can maintain the same value and therefore does not need to resettle when VCO frequency is ramping, provided the KVCO can simultaneously change with FBDIV in equal ratio.

$${F}_{VCO} = {F}_{REF} * FBDIV \qquad ( 2 )$$

$${F}_{VCO} = VDDVCO * {K}_{VCO} \qquad ( 3 )$$

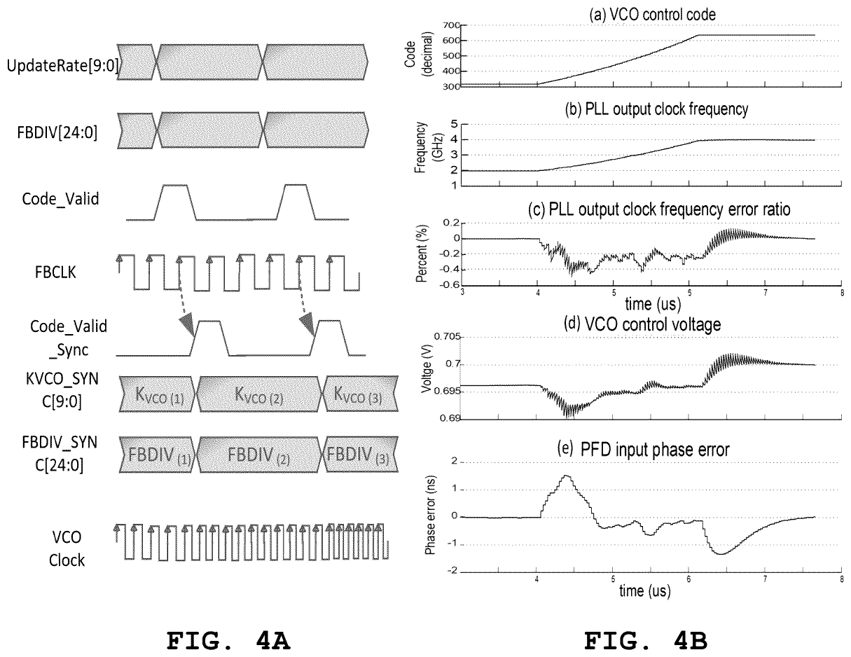

As shown in FIG. 3, SFFFD 302 comprises a series of delay flip flops (DFFs) 320, 322, 324, and a multiplier 326. Referring now also to FIG. 4A, which illustrates a timing diagram for SFFFD 302, SFFFD 302 computes KVCO_SYNC[0:9](also referred to herein as KVCO code or VCO Frequency Code) from UpdateRate[9:0]*FBDIV[24:0] at multiplier 326, where UpdateRate[9:0] is a code denoting the REFCLK frequency (FREF). Control signal Code_Valid is asserted in the FBCLK domain at DFF 310 and used to clock DFFs 322, 324. KVCO and the FBDIV are updated simultaneously via KVXO_SYNC[9:0] and FBDIV_SYNC[24:0] output from DFFs 324 and 326, respectively. FIG. 4B illustrates the frequency ramping behavior of SFFFD (FIG. 3) via MATLAB modeling.

In summary, SFFFD 302 synchronizes updates to both FFD 306 and scalable VCO 304, ensuring that the VCO control voltage remains stable during frequency ramping. This minimizes overshoot (e.g., <1.5%) and keeps period jitter low, even during rapid (e.g., 4×) frequency changes.

SFFFD 302 computes the new KVCO value based on the updated FBDIV and the reference clock frequency (FREF). Both KVCO and FBDIV are updated simultaneously, controlled by Code_Valid in the FBCLK domain. The foregoing ensures the VCO control voltage (VDDVCO) remains stable during frequency ramping, minimizing overshoot and keeping period jitter low.

### Exemplary Multi-Rings VCO of Linear Scaling KVCO for Fractional-N PLL

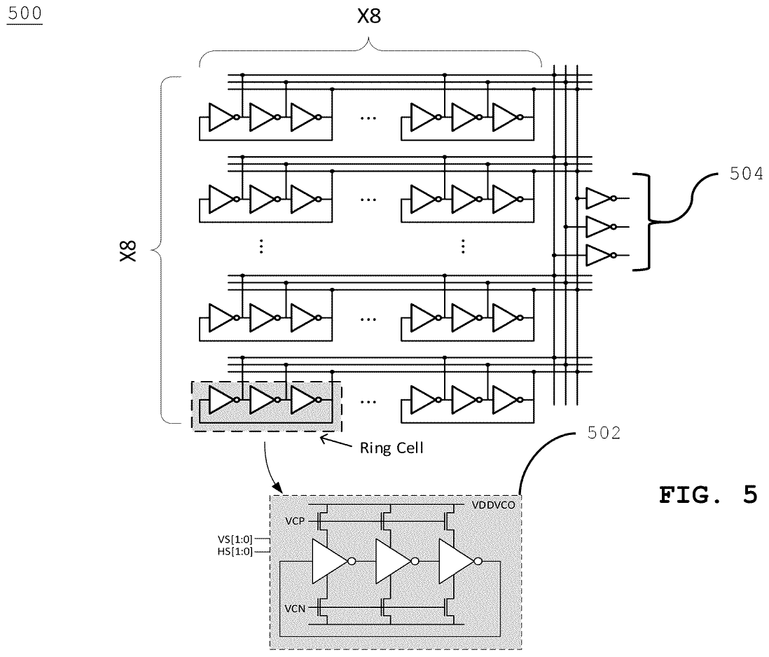

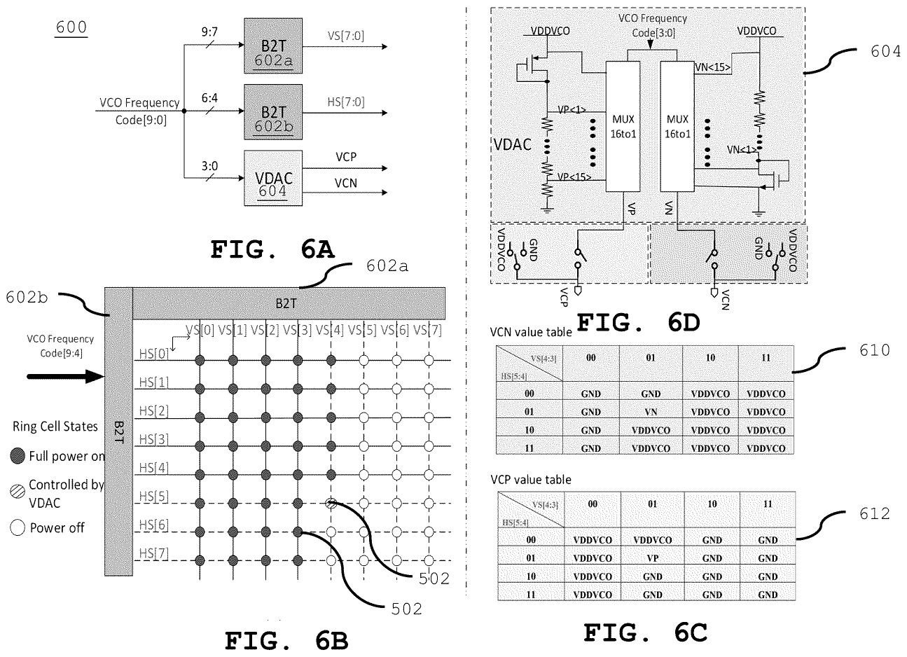

Achieving KVCO changes with FBDIV in equal ratio is crucial for maintaining VDDVCO stable when the frequency of the PLL is updated. As shown in FIG. 5, linear scaling KVCO is achieved with a VCO comprising an 8×8 ring cell matrix 500. Each ring cell 502 comprises a 3-stage inverter-based ring VCO the transconductance (Gm) of which is controlled by VCP and VCN. Output clock signals from ring cells 502 are shorted at inputs to inverters 504 together to ensure resonant oscillation, with three clock phases buffered for output from symmetric nodes. Since the VCO frequency is proportional to Gm/C, turning on/off the sub-rings can change Gm proportionally, thus achieving KVCO linear scaling with FBDIV. FIG. 6A illustrates a 10-bit KVCO code decoder 600. Two 3-bit binary-to-thermal code encoders (B2T) 602a, 602b, convert the 3-bit KVCO codes [9:7] and [6:4], respectively, to thermal codes comprising vertical selection signals (VS [7:0]) and horizontal selection signals (HS [7:0]). The 4-bit KVCO code [3:0] is input to a 4-bit digital-to-analog converter (DAC) 604 to generate bias voltage signals VCP, VCN.

FIGS. 6B and 6C illustrate the decoder scheme through use of an example. As illustrated in FIG. 6B, only one ring cell is controlled by the DAC for a given KVCO[9:0]. Theoretically, the KVCO code resolution is 16 GHz/2¹⁰=16 MHz. FIG. 6C illustrates tables 610, 612, respectively illustrating values of VCN and VCP for the particular combination of VS[4:3] and HS[5:4].

The foregoing enables precise, linear scaling of KVCO, allowing the PLL to ram frequency smoothly and predictably and supports high-frequency operation (e.g., up to 16 GHz) with fine resolution (e.g., 16 MHz per KVCO code step).

### Exemplary Fractional Feedback Divider for Fractional-N PLL

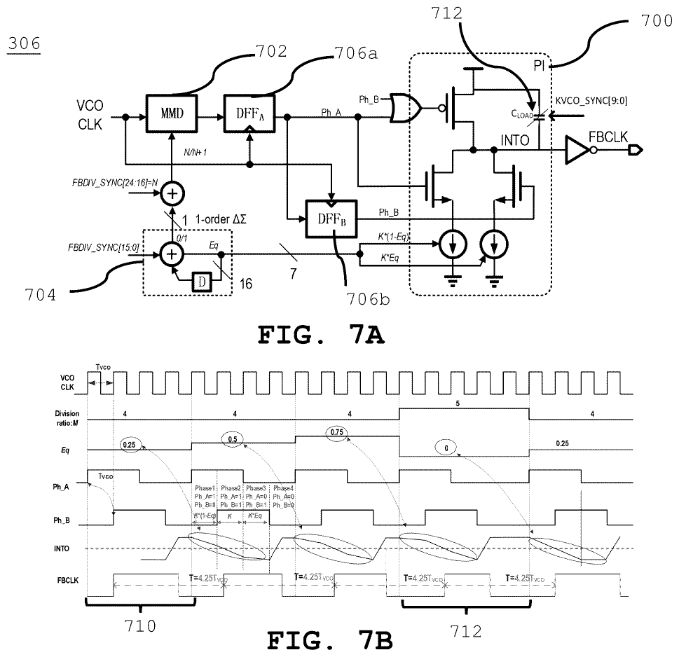

As noted above, Equation (1) expresses the PLL output frequency FVCO where FBDIV[24:15] is the integer part and FBDIV[14:0] is the fractional part of the feedback divider ratio, FREF is the REFCLK frequency, and P is a post divider code. Rather than using a phase rotator working on % FVCO, as may be employed in previous systems, as shown in FIG. 7A, FFD 306 includes a 6-bit phase interpolator (PI) 700 operating in the FBCLK clock domain, which consumes much less power. Additionally, PI 700 reduces the resolution of the FFD 306, achieving a smaller division of the VCO clock cycle.

A multi-modulus divider (MMD) 702 divides the VCOCLK by N or N+1 as controlled by a 1-order ΔΣ modulator 704. The output phase of FBCLK is adjusted by PI 700 interpolating between Ph_A and Ph_B, which have a phase gap of TVCO, which is the period of the VCOCLK signal. In the illustrated embodiment Ph_A and Ph_B are respectively output from delay flip flops (DFFs) 706a and 706b, which are clocked by VCOCLK. PI 700 improves the FBCLK phase adjustment resolution from TVCO to 1/64*TVCO, reducing PLL spur jitter significantly. The quantization error (Eq), representing the fractional part of the AI output, controls the weight of the tail current source of Ph_A and Ph_B, thereby tuning the FBCLK phase in proportion to Eq. FIG. 7B illustrates a timing diagram for an example N+α=4.25, where α=FBDIV_SYNC[15:0]/2¹⁶. Eq controls the falling edge slope of INTO to define the inversion time of FBCLK. Referring now to FIGS. 7A and 7B collectively, as long as INTO does not exceed the inverter threshold voltage in Phasel 710, PI 700 (FIG. 7A) will achieve acceptable linearity. To support large frequency scaling, the value of a capacitor C_{LOAD} 712 is updated on the fly at the Phase4 714 by the reciprocal of KVCO_SYNC code. Changing the value of C_{LOAD} 712 impacts the slope of INTO, thereby affecting the reaction time of PI 700.

The fractional-N function achieved by PI 700 only consumes power of 4.6% and 1.4% at VCO frequencies of 4 GHz and 16 GHz, as shown in TABLE I below.

TABLE I

| | VCO = 4 GHz Mode | | VCO = 16 GHz Mode | |
|---|---|---|---|---|
| VCO | 2.53 mW | (43.3%) | 12.2 mW | (60.3%) |
| Post Divider & Regulator | 1.81 mW | (30.9%) | 4.83 mW | (23.8%) |
| MMD & VCO Clock Feedback | 0.51 mW | (8.8%) | 2.19 mW | (10.8%) |
| Path | | | | |
| PFD&CP&V2I&LPF | 0.38 mW | (6.5%) | 0.4 mW | (2.0%) |
| SFFFD | 0.35 mW | (5.9%) | 0.35 mW | (1.7%) |
| PI | 0.27 mW | (4.6%) | 0.3 mW | (1.4%) |
| Total | 5.8 mW | (100%) | 20.27 mW | (100%) |

Referring again to FIG. 3, as previously noted, fractional-N PLL 300 implemented in 3 nm FinFET technology, occupies approximately 0.01275 mm². Due to the presence of SFFFD 302, the overshoot is significantly reduced at the 4× and 2× frequency ramping at different step sizes. The multi-steps ramping strategy can further reduce the overshoot to less than 1.5% and fractional-N PLL 300 may achieve in-band spur jitter of approximately 826 fs. The overall measured RMS jitter integrated from 10 KHz to 1 GHz may be approximately 1.12 ps. Fractional N-PLL 300 achieves a large on-the-fly frequency ramping range with a small frequency overshoot.

### SELECT EXAMPLES

Example 1 provides a fractional-N phase locked loop (PLL), including a synchronized feed forward frequency decoder (SFFFD) configured to generate a VCO frequency code from a feedback divider ratio and an update rate input thereto; and a scalable voltage-controlled oscillator (VCO) including an array of ring cells, in which each of the ring cells includes a multi-stage ring VCO including a plurality of inverters; in which a transconductance of each of the ring cells is controlled by bias voltage signals applied to a selected one of the ring cells.

Example 2 provides the fractional-N PLL or example 1, in which the scalable VCO further includes a digital-to-analog converter (DAC) and in which the bias voltage signals are generated by the DAC from a first portion of the VCO frequency code.

Example 3 provides the fractional-N PLL of example 1 or 2, in which the scalable VCO further includes first and second binary-to-thermal code encoders (B2T) for outputting vertical and horizontal selection signals, respectively.

Example 4 provides the fractional-N PLL of example 3, in which the vertical and horizontal selection signals are generated by the first and second B2 Ts, respectively, from second and third portions of the VCO frequency code.

Example 5 provides the fractional-N PLL of example 4, in which each of the second and third portions of the VCO frequency code includes three-bit portions.

Example 6 provides the fractional-N PLL of example 4 or 5, in which a combination of the vertical and horizontal selection signals identifies a unique one of the ring cells of the array of ring cells.

Example 7 provides the fractional-N PLL of any one of examples 1-6, in which the array of ring cells includes an 8×8 array.

Example 8 provides the fractional-N PLL of any one of examples 1-7, in which each of the ring cells includes a three-stage inverter-based ring.

Example 9 provides the fractional-N PLL of example 8, in which output clock signals are shorted at inputs to the inverters.

Example 10 provides the fractional-N PLL of any one of examples 1-9, in which the SFFFD includes a series of delay flip flops (DFFs).

Example 11 provides the fractional-N PLL of any one of examples 1-10, in which the SFFFD generates the VCO frequency code by multiplying the feedback divider ratio and the update rate input thereto.

Example 12 provides a scalable voltage-controlled oscillator (VCO) including an array of ring cells, in which each of the ring cells includes a multi-stage ring VCO including a plurality of inverters; a digital-to-analog (DAC) converter configured to generate first and second bias voltage signals, in which a transconductance of a selected one of the ring cells is controlled by applying the first and second bias voltage signals to the selected one of the ring cells.

Example 13 provides the scalable VCO of example 12, in which the bias voltage signals are generated by the DAC from a first portion of a VCO frequency code applied to the scalable VCO.

Example 14 provides the scalable VCO of example 13, further including first and second binary-to-thermal code encoders (B2T) for outputting vertical and horizontal selection signals, respectively.

Example 15 provides the scalable VCO of example 14, in which the vertical and horizontal selection signals are generated by the first and second B2 Ts, respectively, from second and third portions of the VCO frequency code.

Example 16 provides the scalable VCO of example 15, in which the first portion of the VCO frequency code includes a four-bit portion and each of the second and third portions of the VCO frequency code includes three-bit portions.

Example 17 provides the scalable VCO of any one of examples 14-16, in which a combination of the vertical and horizontal selection signals identifies a selected one of the ring cells of the array of ring cells.

Example 18 provides the scalable VCO of any one of examples 12-17, in which each of the ring cells includes a three-stage inverter-based ring.

Example 19 provides an apparatus including a first circuit for generating a voltage-controlled oscillator gain sync code (KVCO_SYNC) from a feedback divider ratio and an update rate input thereto; a second circuit for generating a feedback divider ratio sync code (FBDIV_SYNC) from the feedback divider ratio input thereto; in which the KVCO_SYNC code is provided to a scalable voltage-controlled oscillator (VCO) for controlling operation thereof, and in which the KVCO_SYNC code and the FBDIV_SYNC code are provided to a fractional divider for controlling operation thereof.

Example 20 provides the apparatus of example 19, in which the first circuit includes a multiplier and a first delay flip flop (DFF) and the second circuit includes second and third DFFs.

### Variations and Other Notes

The detailed description, such as the “Select examples” section, provide various examples of the embodiments disclosed herein.

As used herein, the term “coupled to” or “coupled with” refers to a relationship between electronic components or circuit elements wherein the components are in electronic communication with one another and capable of transmitting and/or receiving electrical signals between them. The term “coupled to” does not require a direct physical or electrical connection between the coupled components. Rather, “coupled to” can encompass arrangements where the components are connected through one or more intervening elements, components, circuits, or transmission paths. For example, a first component may be “coupled to” a second component through intermediate components such as resistors, capacitors, inductors, transistors, logic gates, buses, transformers, or other electronic components, or through intermediate transmission paths, while still maintaining the capability for electronic communication between the first and second components.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

For purposes of explanation, specific numbers, materials, and configurations are set forth in order to provide a thorough understanding of the illustrative implementations. However, it will be apparent to one skilled in the art that the present disclosure may be practiced without the specific details and/or that the present disclosure may be practiced with only some of the described aspects. In other instances, well known features are omitted or simplified in order not to obscure the illustrative implementations.

Further, references are made to the accompanying drawings that form a part hereof, and in which are shown, by way of illustration, embodiments that may be practiced. It is to be understood that other embodiments may be utilized, and structural or logical changes may be made without departing from the scope of the present disclosure. Therefore, the following detailed description is not to be taken in a limiting sense.

Various operations may be described as multiple discrete actions or operations in turn, in a manner that is most helpful in understanding the disclosed subject matter. However, the order of description should not be construed as to imply that these operations are necessarily order dependent. In particular, these operations may not be performed in the order of presentation. Operations described may be performed in a different order from the described embodiment. Various additional operations may be performed or described operations may be omitted in additional embodiments.

For the purposes of the present disclosure, the phrase “A or B” or the phrase “A and/or B” means (A), (B), or (A and B). For the purposes of the present disclosure, the phrase “A, B, or C” or the phrase “A, B, and/or C” means (A), (B), (C), (A and B), (A and C), (B and C), or (A, B, and C). The term “between,” when used with reference to measurement ranges, is inclusive of the ends of the measurement ranges.

The description uses the phrases “in an embodiment” or “in embodiments,” which may each refer to one or more of the same or different embodiments. The terms “comprising,” “including,” “having,” and the like, as used with respect to embodiments of the present disclosure, are synonymous. The disclosure may use perspective-based descriptions such as “above,” “below,” “top,” “bottom,” and “side” to explain various features of the drawings, but these terms are simply for ease of discussion, and do not imply a desired or required orientation. The accompanying drawings are not necessarily drawn to scale. Unless otherwise specified, the use of the ordinal adjectives “first,” “second,” and “third,” etc., to describe a common object, merely indicates that different instances of like objects are being referred to and are not intended to imply that the objects so described must be in a given sequence, either temporally, spatially, in ranking or in any other manner.

In the following detailed description, various aspects of the illustrative implementations will be described using terms commonly employed by those skilled in the art to convey the substance of their work to others skilled in the art.

The terms “substantially,” “close,” “approximately,” “near,” and “about,” generally refer to being within +/−20% of a target value as described herein or as known in the art. Similarly, terms indicating orientation of various elements, e.g., “coplanar,” “perpendicular,” “orthogonal,” “parallel,” or any other angle between the elements, generally refer to being within +/−5-20% of a target value as described herein or as known in the art.

In addition, the terms “comprise,” “comprising,” “include,” “including,” “have,” “having” or any other variation thereof, are intended to cover a non-exclusive inclusion. For example, a method, process, or device, that comprises a list of elements is not necessarily limited to only those elements but may include other elements not expressly listed or inherent to such method, process, or device. Also, the term “or” refers to an inclusive “or” and not to an exclusive “or.”

The systems, methods, and devices of this disclosure each have several innovative aspects, no single one of which is solely responsible for all desirable attributes disclosed herein. Details of one or more implementations of the subject matter described in this specification are set forth in the description and the accompanying drawings.

1. A fractional-N phase locked loop (PLL), comprising:
a synchronized feed forward frequency decoder (SFFFD) configured to generate a VCO frequency code from a feedback divider ratio and an update rate input thereto; and
a scalable voltage-controlled oscillator (VCO) comprising an array of ring cells, wherein each of the ring cells comprises a multi-stage ring VCO comprising a plurality of inverters;
wherein a transconductance of each of the ring cells is controlled by bias voltage signals applied to a selected one of the ring cells.

2. The fractional-N PLL or claim 1, wherein the scalable VCO further comprises a digital-to-analog converter (DAC) and wherein the bias voltage signals are generated by the DAC from a first portion of the VCO frequency code.

3. The fractional-N PLL of claim 1, wherein the scalable VCO further comprises first and second binary-to-thermal code encoders (B2T) for outputting vertical and horizontal selection signals, respectively.

4. The fractional-N PLL of claim 3, wherein the vertical and horizontal selection signals are generated by the first and second B2 Ts, respectively, from second and third portions of the VCO frequency code.

5. The fractional-N PLL of claim 4, wherein each of the second and third portions of the VCO frequency code comprises three-bit portions.

6. The fractional-N PLL of claim 4, wherein a combination of the vertical and horizontal selection signals identifies a unique one of the ring cells of the array of ring cells.

7. The fractional-N PLL of claim 1, wherein the array of ring cells comprises an 8×8 array.

8. The fractional-N PLL of claim 1, wherein each of the ring cells comprises a three-stage inverter-based ring.

9. The fractional-N PLL of claim 8, wherein output clock signals are shorted at inputs to the inverters.

10. The fractional-N PLL of claim 1, wherein the SFFFD comprises a series of delay flip flops (DFFs).

11. The fractional-N PLL of claim 1, wherein the SFFFD generates the VCO frequency code by multiplying the feedback divider ratio and the update rate input thereto.

12. A scalable voltage-controlled oscillator (VCO) comprising:
an array of ring cells, wherein each of the ring cells comprises a multi-stage ring VCO comprising a plurality of inverters;
a digital-to-analog (DAC) converter configured to generate first and second bias voltage signals, wherein a transconductance of a selected one of the ring cells is controlled by applying the first and second bias voltage signals to the selected one of the ring cells.

13. The scalable VCO of claim 12, wherein the bias voltage signals are generated by the DAC from a first portion of a VCO frequency code applied to the scalable VCO.

14. The scalable VCO of claim 13, further comprising first and second binary-to-thermal code encoders (B2T) for outputting vertical and horizontal selection signals, respectively.

15. The scalable VCO of claim 14, wherein the vertical and horizontal selection signals are generated by the first and second B2 Ts, respectively, from second and third portions of the VCO frequency code.

16. The scalable VCO of claim 15, wherein the first portion of the VCO frequency code comprises a four-bit portion and each of the second and third portions of the VCO frequency code comprises three-bit portions.

17. The scalable VCO of claim 14, wherein a combination of the vertical and horizontal selection signals identifies a selected one of the ring cells of the array of ring cells.

18. The scalable VCO of claim 12, wherein each of the ring cells comprises a three-stage inverter-based ring.

19. An apparatus comprising:
a first circuit for generating a voltage-controlled oscillator gain sync code (KVCO_SYNC) from a feedback divider ratio and an update rate input thereto;
a second circuit for generating a feedback divider ratio sync code (FBDIV_SYNC) from the feedback divider ratio input thereto;
wherein the KVCO_SYNC code is provided to a scalable voltage-controlled oscillator (VCO) for controlling operation thereof, and wherein the KVCO_SYNC code and the FBDIV_SYNC code are provided to a fractional divider for controlling operation thereof.

20. The apparatus of claim 19, wherein the first circuit comprises a multiplier and a first delay flip flop (DFF) and the second circuit comprises second and third DFFs.
